(19) United States
(12) Patent Application Publication
(10) Pub. No.: US 2026/0114063 A1
(43) Pub. Date: Apr. 23, 2026

(54) IMAGE SENSOR

(71) Applicant: Samsung Electronics Co., Ltd., Suwon-si (KR)

(72) Inventors: JAESANG YOO, Suwon-si (KR); Shinyoung Choi, Suwon-si (KR); SungMin Kwon, Suwon-si (KR); Yeji Kwon, Suwon-si (KR); DONGJIN KIM, Suwon-si (KR); Yongmin Yang, Suwon-si (KR)

(21) Appl. No.: 19/241,001

(22) Filed: Jun. 17, 2025

(30) Foreign Application Priority Data
Oct. 23, 2024 (KR) 10-2024-0145827

(51) Int. Cl. H10F 39/00; H10F 39/18

(52) U.S. Cl. CPC H10F 39/8057; H10F 39/024; H10F 39/182; H10F 39/8023; H10F 39/8053; H10F 39/8063

(57) ABSTRACT

An image sensor comprising a substrate including a pixel array region and an optical black region provided at one side of the pixel array region, and having a first surface and a second surface that are opposite to each other, the second surface being a light incident surface, a blocking pattern provided on the second surface of the substrate and overlapping the optical black region, a filtering pattern provided on the blocking pattern, and a passivation pattern covering the blocking pattern and the filtering pattern. The passivation pattern includes a inclined portion in which a level of at least a portion of an upper surface decreases as the inclined portion extends away from the pixel array region.

### CROSS-REFERENCE TO RELATED APPLICATION(S)

This U.S. non-provisional application claims priority under 35 USC § 119 to Korean Patent Application No. 10-2024-0145827, filed on Oct. 23, 2024, in the Korean Intellectual Property Office, the disclosure of which is herein incorporated by reference in its entirety.

### BACKGROUND

The present disclosure relates to an image sensor, and more specifically, to an image sensor including a passivation pattern provided on an optical black region.

An image sensor is a semiconductor element that converts an optical image into an electrical signal. Recently, with the development of the computer industry and the communication industry, the demand for image sensors with improved performance has increased in various fields such as digital cameras, camcorders, personal communication systems (PCSs), gaming devices, security cameras, and medical micro cameras. The Image sensors can be classified into a charge coupled device (CCD) type and a complementary metal oxide semiconductor (CMOS) type. The CMOS type image sensor is provided with a plurality of pixels arranged two-dimensionally. Each of the pixels includes a photodiode (PD). The photodiode serves to convert incident light into an electrical signal.

### SUMMARY

One technical object of the present disclosure is directed to providing an image sensor with reduced flare phenomenon.

According to an example embodiment, an image sensor includes a substrate including a pixel array region and an optical black region provided at one side of the pixel array region, and having a first surface and a second surface that are opposite to each other, the second surface being a light incident surface, a blocking pattern provided on the second surface of the substrate and overlapping the optical black region, a filtering pattern provided on the blocking pattern, and a passivation pattern covering the blocking pattern and the filtering pattern, wherein the passivation pattern may include an inclined portion in which a level of at least a first portion of an upper surface thereof decreases as the inclined portion extends away from the pixel array region.

The first portion of the upper surface of the inclined portion may have a downward slope in a direction away from the pixel array region.

The first portion of the upper surface of the inclined portion may be concave in a downward direction.

The passivation pattern may further include a dummy lens portion between the pixel array region and the inclined portion, and the dummy lens portion may include a plurality of dummy lenses arranged laterally.

Levels of upper ends of the plurality of dummy lenses with respect to the second surface of the substrate may decrease in a direction from the pixel array region toward the inclined portion.

Horizontal widths of the plurality of dummy lenses may decrease in the direction from the pixel array region toward the inclined portion.

A level of the uppermost end of the inclined portion with respect to the second surface of the substrate may be lower than the levels of the upper ends of the plurality of dummy lenses.

Upper surfaces of the dummy lenses may be curved surfaces that are convex in an upward direction, and a first vertical distance from an upper surface of the filtering pattern to a lower end of the upper surface of the dummy lens closest to the pixel array region may be larger than a second vertical distance from the upper surface of the filtering pattern to a lower end of the at least a portion of the upper surface of the inclined portion.

The second vertical distance may be equal to or greater than 65% and less than 100% of the first vertical distance.

Upper surfaces of the dummy lenses may be curved surfaces that are convex in an upward direction, a third vertical distance from an upper surface of the filtering pattern to an upper end of the upper surface of the dummy lens closest to the pixel array region may be larger than a second vertical distance from the upper surface of the filtering pattern to a lower end of the at least a portion of the upper surface of the inclined portion, and the second vertical distance may be about 5% to about 35% times the third vertical distance.

The passivation pattern may further include an edge portion extending from the inclined portion and surrounding one end portion of the blocking pattern and one end portion of the filtering pattern, and a level of an upper surface of the edge portion with respect to the second surface of the substrate decreases as the edge portion extends away from the inclined portion.

The upper surface of the edge portion may have a downward slope in a direction away from the inclined portion.

The upper surface of the edge portion may be steeper than the first portion of the upper surface of the inclined portion.

An inclination angle between the second surface of the substrate and the upper surface of the edge portion may be equal to or greater than 80 degrees and less than 90 degrees, and an inclination angle between the second surface of the substrate and the first portion of the upper surface of the inclined portion may be larger than 0 degrees and less than or equal to 10 degrees.

The passivation pattern may further include a protrusion connected to one end portion of the inclined portion, and the protrusion may protrude in an upward direction from one end of the upper surface of the inclined portion and have a flat upper surface.

The image sensor may further include color filters provided on the second surface of the substrate and overlapping the pixel array region, and microlenses covering the color filters, wherein the passivation pattern may include the same material as the microlenses.

The filtering pattern may include a blue color filter that transmits blue light, and the blocking pattern may include a metal.

According to an example embodiment, an image sensor includes a substrate including a pixel array region and an optical black region provided at one side of the pixel array region, and having a first surface and a second surface that are opposite to each other, the second surface being a light incident surface, a blocking pattern provided on the second surface of the substrate and overlapping the optical black region, a filtering pattern provided on the blocking pattern, and a passivation pattern covering the blocking pattern and the filtering pattern, wherein the passivation pattern may include dummy lenses arranged laterally, and levels of upper ends of the dummy lenses with respect to the second surface of the substrate may decrease as the dummy lenses extend away from the pixel array region.

Upper surfaces of the dummy lenses may be curved surfaces that are convex in an upward direction, and levels of lower ends of the upper surfaces of the dummy lenses with respect to the second surface of the substrate may decrease as the dummy lenses extend away from the pixel array region.

Horizontal widths of the dummy lenses may decrease as the dummy lenses extend away from the pixel array region.

### BRIEF DESCRIPTION OF DRAWINGS

FIG. 1 is a plan view showing an image sensor according to some embodiments of the present disclosure.

FIG. 2 is a cross-sectional view taken along line I-I′ of FIG. 1.

FIG. 3 is a cross-sectional view of an image sensor according to one embodiment of the present disclosure.

FIGS. 4 to 8 show a manufacturing method of an image sensor according to some embodiments of the present disclosure, which are cross-sectional views corresponding to line I-I′ of FIG. 1,

FIG. 9 is a cross-sectional view of an image sensor according to one embodiment of the present disclosure.

FIG. 10 is a cross-sectional view of an image sensor according to one embodiment of the present disclosure.

FIG. 11 is a cross-sectional view of an image sensor according to one embodiment of the present disclosure.

FIG. 12 is a cross-sectional view of an image sensor according to one embodiment of the present disclosure.

FIG. 13 is a cross-sectional view of an image sensor according to one embodiment of the present disclosure.

FIG. 14 is a cross-sectional view of an image sensor according to one embodiment of the present disclosure.

### DETAILED DESCRIPTION

Hereafter, the embodiments of the present disclosure will be clearly and thoroughly described with reference to the accompanying drawings.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

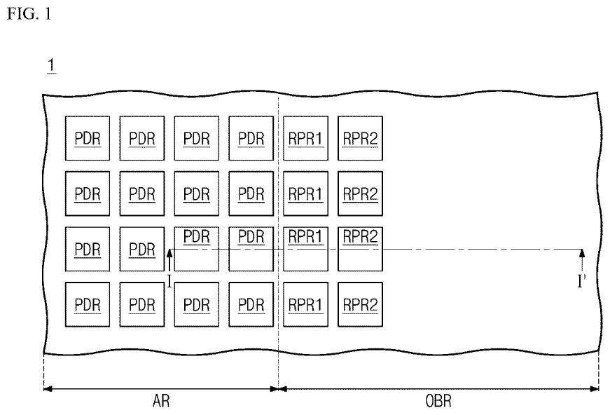

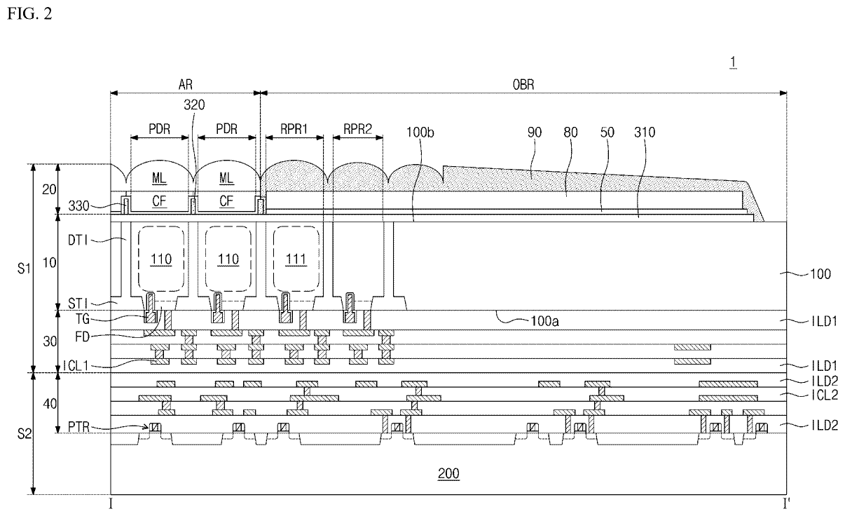

FIG. 1 is a plan view showing an image sensor 1 according to some embodiments of the present disclosure. FIG. 2 is a cross-sectional view taken along line I-I′ of FIG. 1.

Referring to FIG. 1 and FIG. 2, the image sensor 1 according to some embodiments of the present disclosure may include a first structure S1 and a second structure S2. The first structure S1 may be stacked on the second structure S2. For example, the image sensor 1 may have a stacked structure. The first structure S1 may be referred to as a sensor chip or a first chip. The second structure S2 may be referred to as a logic chip or a second chip. The first structure S1 and the second structure S2 may be bonded to each other by at least one of various bonding methods and electrically connected to each other by at least one of various connection methods.

The first structure S1 may include a photoelectric conversion layer 10, a light-transmitting layer 20, and a first wiring layer 30. The photoelectric conversion layer 10 may be disposed between the light-transmitting layer 20 and the first wiring layer 30. The photoelectric conversion layer 10 may include a first substrate 100, and the first substrate 100 may include a pixel array region AR and an optical black region OBR. The first substrate 100 may have a first surface 100a and a second surface 100b that face each other. In some embodiments, the first substrate 100 may be a semiconductor substrate (for example, a silicon (Si) substrate, a germanium (Ge) substrate, or a silicon-germanium (SiGe) substrate).

The optical black region OBR may be disposed at one side of the pixel array region AR in a plan view. In some embodiments, the optical black region OBR may surround the pixel array region AR in a plan view. For example, in a plan view, the pixel array region AR may correspond to a central portion of the first substrate 100, and the optical black region OBR may correspond to an edge portion of the first substrate 100. However, the embodiments of the present disclosure are not limited thereto. In some embodiments, the optical black region OBR may be provided at one or some of four sides of the pixel array region AR in a plan view.

In one embodiment, the substrate 100 may further include a pad region PR. The optical black region OBR may be disposed between the pixel array region AR and the pad region PR. The pad region PR may surround the pixel array region AR and the optical black region OBR in a plan view. For example, in a plan view, the pixel array region AR may correspond to the central portion of the first substrate 100, the pad region PR may correspond to the edge portion of the first substrate 100, and the optical black region OBR may be located between the pixel array region AR and the pad region PR.

A deep element isolation pattern DTI may be provided within the first substrate 100 to define a plurality of photodiode regions PDR. The photodiode regions PDR may be defined in the pixel array region AR. The deep element isolation pattern DTI may also be provided in the optical black region OBR to define one or more reference photodiode regions RPR1, RPR2 in the optical black region OBR. In some embodiments, the reference photodiode regions RPR may include a first reference photodiode region RPR1 and a second reference photodiode region RPR2.

A shallow element isolation pattern STI may be provided within the first substrate 100 to define at least one active region in each of the photodiode regions PDR. In addition, the shallow element isolation pattern STI may define at least one active region in each of the first and second reference photodiode regions RPR1, RPR2. The shallow element isolation pattern STI may be adjacent to the first surface 100a of the first substrate 100.

Photodiodes 110 may be provided in the photodiode regions PDR, respectively. In some embodiments, a reference photodiode 111 may be provided in the first reference photodiode region RPR1. The first substrate 100 may be doped with dopants having a first conductivity type, and the photodiodes 110 and the reference photodiode 111 may be doped with dopants having a second conductivity type different from the first conductivity type. For example, the first conductivity type may be a P-type, and the second conductivity type may be an N-type. The second reference photodiode region RPR2 may not include the photodiode.

A floating diffusion region FD may be provided in corresponding active region of each of the photodiode regions PDR. The floating diffusion region FD may be doped with dopants having the second conductivity type. A transfer gate TG may be provided on the corresponding active region of one side of the floating diffusion region FD. A gate dielectric film may be disposed between the transfer gate TG and the corresponding active region. In some embodiments, the transfer gate TG may fill a gate recess formed in the corresponding active region. In this case, the gate dielectric film may extend to be disposed between the transfer gate TG and an inner surface of the gate recess.

In some embodiments, other gates (not shown) may be provided on the active regions with the corresponding gate dielectric film interposed therebetween. The other gates may include a reset gate, a source/follower gate, and a selection gate. In some embodiments, the other gates may further include a gate performing another function (e.g., a dual conversion gain gate). Source/drain regions may be provided in the active region at both sides of each of the other gates. The other gates may be provided on the corresponding active regions of each of the photodiode regions PDR. Alternatively, the other gates may be provided on the corresponding active regions of the photodiode regions PDR of the pixels sharing the other gates.

As described above, the transfer gate TG and the other gates may be provided on the first surface 100a of the first substrate 100. However, the embodiments of the present disclosure are not limited thereto. In some embodiments, the transfer gate TG may be provided on the first surface 100a of the first substrate 100, and the other gates may be provided on an additional substrate (not shown). The additional substrate may have a third surface facing the first surface 100a and a fourth surface opposite to the third surface. The other gates may be provided on the third surface or the fourth surface of the additional substrate with an additional gate dielectric film interposed therebetween. An intermediate structure (not shown) including the additional substrate and the other gates may be provided between the first structure S1 and the second structure S2, and the intermediate structure may be bonded to the first and second structures S1 and S2 by at least one of various bonding methods. Hereafter, for convenience of explanation, the embodiment in which the transfer gate TG and the other gates are provided on the first surface 100a of the first substrate 100 will be continuously described as an example.

The floating diffusion region FD may also be provided in the corresponding active region of each of the first and second reference photodiode regions RPR1 and RPR2, and the transfer gate TG may be provided on the corresponding active regions of the first and second reference photodiode regions RPR1 and RPR2 with the gate dielectric film interposed therebetween. The other gates may be provided on the corresponding active regions of each of the first and second reference photodiode regions RPR1 and RPR2. The floating diffusion region FD, the transfer gate TG, and the other gates of each of the first and second reference photodiode regions RPR1 and RPR2 may have substantially the same forms as the floating diffusion region FD, the transfer gate TG, and the other gates of each of the photodiode regions PDR.

The deep element isolation pattern DTI, the shallow element isolation pattern STI, the photodiodes 110, the reference photodiode 111, the floating diffusion regions FD, and the transfer gates TG may be included in the photoelectric conversion layer 10.

The pixels including the photodiodes 110 of the pixel array region AR may convert incident light into electrical signals (e.g., pixel signals). A first reference pixel may include the reference photodiode 111, the floating diffusion region FD, and the gates of the first reference photodiode region RPR1, and a second reference pixel may include the floating diffusion region FD and the gates of the second reference photodiode region RPR2. The second reference pixel may not include the photodiode. Since the first and second reference pixels are disposed in the optical black region OBR, incident light may not be incident onto the first and second reference pixels. The first reference pixel may generate a first reference charge amount in a dark state to output a first noise signal, and the second reference pixel may generate a second reference charge in the dark state to output a second noise signal. Noise components of the pixel signals output from the pixels in the pixel array region AR can be removed using the first and second noise signals.

The light-transmitting layer 20 may be provided on the second surface 100b of the first substrate 100. The light-transmitting layer 20 may include a transmission insulating film 310, a grid 320, a protective film 330, color filters CF, and microlenses ML.

The transmission insulating film 310 may cover the second surface 100b of the first substrate 100. The transmission insulating film 310 may have a single-layered structure or a multi-layered structure. In some embodiments, the transmission insulating film 310 may include a fixed charge film and/or an anti-reflection film.

The fixed charge film may have negative fixed charges. Therefore, holes may be accumulated at a location adjacent to the fixed charge film, for example, at an interface between the fixed charge film and the first substrate 100 and/or in a portion of the first substrate 100 adjacent to the second surface 100b. As a result, the fixed charge film may effectively reduce a dark current and/or a white spot. In some embodiments, the fixed charge film may be made of a metal oxide or a metal fluoride containing at least one of hafnium Hf, zirconium Zr, aluminum Al, tantalum Ta, titanium Ti, yttrium Y, or a lanthanide. For example, the fixed charge film may be made of a hafnium oxide or an aluminum oxide.

The anti-reflection film can reduce or minimize reflection of light incident on the second surface 100b. For example, the anti-reflection film may include at least one of a titanium oxide, a silicon nitride, a silicon oxide, or a hafnium oxide. When the transmission insulating film 310 includes the fixed charge film and the anti-reflection film, the fixed charge film may be in contact with the second surface 100b of the first substrate 100, and the anti-reflection film may be disposed on the fixed charge film. However, the embodiments of the present disclosure are not limited thereto. In some embodiments, the transmission insulating film 310 may include any one of the fixed charge film and the anti-reflection film, or may further include an additional insulating film.

The grid 320 may have a grid shape with openings in a plan view. In some embodiments, the openings of the grid 320 may vertically overlap the photodiode regions PDR, respectively. The grid 320 may guide incident light so that the incident light is incident into the photodiodes 110. In some embodiments, the grid 320 may include a light-shielding pattern and/or a low refractive pattern. For example, the light-shielding pattern may include at least one of titanium, titanium nitride, tantalum, tantalum nitride, or tungsten. The low refractive pattern may have a refractive index lower than refractive indices of the color filters CF. For example, the low refractive pattern may have a refractive index of about 1.1 to about 1.3. For example, the low refractive pattern may include an organic material. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The protective film 330 may conformally cover a surface (e.g., an upper surface and side surfaces) of the grid 320 and the transmission insulating film 310 exposed by the openings of the grid 320. In some embodiments, the protective film 330 may be made of an insulating material having a high dielectric constant. For example, the protective film 330 may include an aluminum oxide or a hafnium oxide.

The color filters CF may fill the openings of the grid 320. The color filters CF may be disposed on the protective film 330. The color filters CF may vertically overlap the photodiodes 110. In some embodiments, the color filters CF may include a first color filter having a first color, a second color filter having a second color, and a third color filter having a third color. In one embodiment, the first color may be one of red, green, and blue colors, the second color may be another of red, green, and blue colors, and the third color may be the remaining one of red, green, and blue colors. Alternatively, the first color may be one of magenta, cyan, and yellow colors, the second color may be another of magenta, cyan, and yellow colors, and the third color may be the remaining one of magenta, cyan, and yellow colors. However, the embodiments of the present disclosure are not limited thereto. The first to third colors may be various other colors.

As shown in FIG. 2, each of the color filters CF may vertically overlap a corresponding one of the photodiodes 110. However, the embodiments of the present disclosure are not limited thereto. In some embodiments, each of the color filters CF may vertically overlap a plurality of photodiodes 110 that are adjacent to each other. The photodiodes 110 corresponding to each of the color filters CF may be arranged in a matrix form. For example, the corresponding photodiodes 110 may be arranged in a 2×2 matrix form, a 3×3 matrix form, or a 4×4 matrix form.

The microlenses ML may be disposed on the color filters CF. The microlenses ML may condense incident light. As shown in FIG. 2, the microlenses ML may vertically overlap the photodiodes 110. Alternatively, each of the microlenses ML may vertically overlap a plurality of photodiodes 110 that are adjacent to each other. For example, each of the microlenses ML may vertically overlap the photodiodes 110 arranged in a 2×2 matrix form, a 3×3 matrix form, or a 4×4 matrix form. In some embodiments, the number of photodiodes 110 overlapping at least one of the microlenses ML may differ from the number of photodiodes 110 overlapping at least another one of the microlenses ML. For example, the at least one of the microlens ML may vertically overlap a pair of photodiodes 110 that are adjacent to each other, and the at least another one of the microlens ML may vertically overlap a single photodiode 110 or the photodiodes 110 that are adjacent to each other.

Each of the microlenses ML may have a shape that is convex upward in a cross-sectional view. In some embodiments, each of the microlenses ML may have a circular shape or an elliptical shape in a plan view. The microlenses ML may be made of a light-transmitting resin.

Although not shown, an additional protective film may be provided on surfaces of the microlenses ML. The additional protective film may protect the microlenses ML and transmit light. The additional protective film may be made of an organic material and/or an inorganic material. For example, the additional protective film may include at least one of a silicon oxide, a silicon nitride, a silicon oxynitride, a silicon carbide, a silicon carbo-oxide, a silicon carbo-nitride, a silicon carbo-oxynitride, an aluminum oxide, a zinc oxide, or a hafnium oxide.

As shown in FIG. 2, the grid 320 may be vertically aligned with the deep element isolation pattern DTI, and the microlens ML and the color filter CF may be vertically aligned with the corresponding photodiode 110. However, the embodiments of the present disclosure are not limited thereto.

In some embodiments, light may be incident radially onto the entirety of the second surface 100b of the first substrate 100 from an objective lens (not shown) overlapping a central portion of the pixel array region AR. For example, incident light may be substantially vertically incident onto the photodiodes 110 in the central portion of the pixel array region AR, but may be obliquely incident onto the photodiodes 110 in an edge portion of the pixel array region AR. In this case, the grid 320 on the central portion of the pixel array region AR may be vertically aligned with the deep element isolation pattern DTI, and the microlens ML and color filter CF on the central portion of the pixel array region AR may be vertically aligned with the corresponding photodiode 110. In contrast, the grid 320 on the edge portion of the pixel array region AR may be shifted laterally from the deep element isolation pattern DTI, and the microlens ML and color filter CF on the edge portion of the pixel array region AR may be shifted laterally from the corresponding photodiode 110. The grid 320, the microlenses ML, and the color filters CF on the edge portion of the pixel array region AR may be shifted laterally in a direction toward the central portion from the edge portion of the pixel array region AR. In some embodiments, the shifted degrees of portions of the grid 320, the microlenses, and the color filters CF on the edge portion of the pixel array region AR may sequentially decrease in the direction toward the central portion from the edge portion of the pixel array region AR.

The first wiring layer 30 may be provided on the first surface 100a of the first substrate 100. The first wiring layer 30 may cover the first surface 100a of the first substrate 100 and include first insulating films ILD1 and first wiring lines ICL1. The first wiring lines ICL1 may be provided between the first interlayer insulating films ILD1. The first wiring lines ICL1 may be electrically connected to pixel transistors (e.g., the transfer transistor, the reset transistor, the source follower transistor, and the selection transistor) and/or may electrically connect the pixel transistors through first contact plugs.

The second structure S2 may include a second substrate 200, peripheral transistors PTR formed on an upper surface of the second substrate 200, and a second wiring layer 40 provided on the upper surface of the second substrate 200 to cover the peripheral transistors PTR. The second substrate 200 may be a semiconductor substrate such as a silicon substrate, a germanium substrate, or a silicon-germanium substrate. The second wiring layer 40 may include second interlayer insulating films ILD2 and second wiring lines ICL2 between the second interlayer insulating films ILD2. The second wiring lines ICL2 may be electrically connected to the peripheral transistors PTR or may electrically connect the peripheral transistors PTR through second contact plugs. The second wiring lines ICL2 and the peripheral transistors PTR may configure peripheral circuits (e.g., a row decoder, a row driver, a column decoder, a timing generator, a correlated double sampler, an analog-to-digital converter, and/or an input/output buffer) of the image sensor 1.

The first structure S1 may be stacked on the second structure S2, and the first and second structures S1 and S2 may be bonded to each other. The second wiring layer 40 may be disposed between the first wiring layer 30 and the second substrate 200. In some embodiments, the lowermost film among the first interlayer insulating films ILD1 included in the first wiring layer 30 may be bonded to the uppermost film among the second interlayer insulating film ILD2 included in the second wiring layer 40.

The transmission insulating film 310 may also be provided in the optical black region OBR. For example, the transmission insulating film 310 may be provided on the second surface 100b of the first substrate 100 corresponding to the optical black region OBR. The transmission insulating film 310 in the pixel array region AR may extend to the optical black region OBR. However, the embodiments of the present disclosure are not limited thereto. In some embodiments, an additional insulating film may be provided on the second surface 100b of the substrate 100 corresponding to the optical black region OBR. In this case, the transmission insulating film 310 may be provided on the additional insulating film.

A blocking pattern 50 may be provided on the transmission insulating film 310. The blocking pattern 50 may vertically overlap the optical black region OBR. The blocking pattern 50 may block at least a portion of light incident onto the optical black region OBR. The blocking pattern 50 may include a metal material. For example, the blocking pattern 50 may include tungsten.

A filtering pattern 80 may be provided on the blocking pattern 50. The filtering pattern 80 may vertically overlap the optical black region OBR. The filtering pattern 80 may block light of a specific wavelength range. For example, the filtering pattern 80 may block ultraviolet light. The filtering pattern 80 may include a blue color filter, but is not limited thereto.

A passivation pattern 90 may be provided on the second surface 100b of the first substrate 100. The passivation pattern 90 may vertically overlap the optical black region OBR. The passivation pattern 90 may cover at least a portion of the optical black region OBR. For example, the passivation pattern 90 may cover at least one of the transmission insulating film 310, the blocking pattern 50, or the filtering pattern 80 provided in the optical black region OBR. In one embodiment, the passivation pattern 90 may be made of the same material as the microlens ML.

Although not shown, the image sensor 1 may further include a third structure. The third structure may be disposed between the first structure S1 and the second structure S2. For example, the third structure may be stacked on the second structure S2, and the first structure S1 may be stacked on the third structure. The third structure may be bonded to the first structure S1 and the second structure S2. The third structure may include a third substrate, gates on the third substrate, and a third wiring layer provided on the third substrate. In this case, the transfer gate TG may be provided in the first structure S1, and at least one of the source follower gate, the reset gate, and the selection gate may be provided on the third substrate.

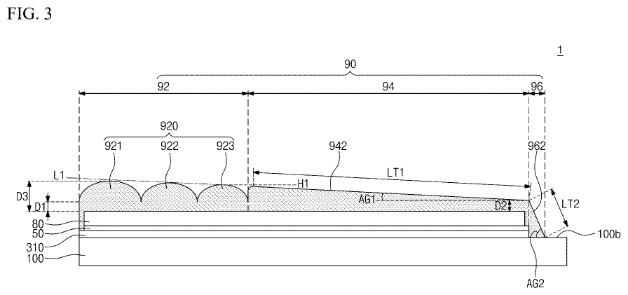

FIG. 3 is a cross-sectional view of an image sensor 1 according to one embodiment of the present disclosure.

The passivation pattern 90 may be provided on the first substrate 100. The first substrate 100 may include a first surface 100a (see FIG. 2) and a second surface 100b that face each other. The second surface 100b of the first substrate 100 may be a surface on which light is incident. For example, the passivation pattern 90 may be provided on the second surface 100b of the first substrate 100 corresponding to the optical black region OBR (see FIG. 2).

In one embodiment, the passivation pattern 90 may include the same material as the microlenses ML (see FIG. 2). For example, the microlenses ML (see FIG. 2) and the passivation pattern 90 may include a light-transmissive organic material.

The passivation pattern 90 may cover at least one of the transmission insulating film 310, the blocking pattern 50, or the filtering pattern 80 that are provided on the first substrate 100. At least one of the transmission insulating film 310, the blocking pattern 50, or the filtering pattern 80 may be provided between the first substrate 100 and the passivation pattern 90.

The passivation pattern 90 may include an upper surface onto which light is incident. A portion of incident light that is incident onto the passivation pattern 90 may be incident onto the filtering pattern 80 by transmitting the passivation pattern 90, and the remaining portion of incident light may be reflected from the upper surface of the passivation pattern 90.

The passivation pattern 90 may include an inclined portion 94. A level of at least a portion of an upper surface of the inclined portion 94 may decrease toward an outward direction. The level may refer to a position in a vertical direction. The vertical direction may be a thickness direction of the first substrate 100. The outward direction may be a direction from a central portion of the first substrate 100 toward an edge of the first substrate 100. The outward direction may also be a direction from the pixel array region AR (see FIG. 2) toward the optical black region OBR (see FIG. 2). Conversely, an inward direction may be an opposite direction to the outward direction.

At least a portion of the upper surface of the inclined portion 94 may be inclined in a downward direction toward the outward direction. For example, the upper surface of the inclined portion 94 may include an inclined surface 942 that is inclined in the downward direction toward the outward direction. The inclined surface 942 may have a downward slope in a direction away from the pixel array region AR (see FIG. 2). A level of the inclined surface 942 may gradually decrease toward the outward direction. For example, the level of the inclined surface 942 may linearly decrease toward the outward direction.

An inclined angle AG1 between the second surface 100b of the first substrate 100 and the inclined surface 942 may be larger than 0 degrees and about 15 degrees or less. For example, the inclined angle AG1 between the second surface 100b of the first substrate 100 and the inclined surface 942 may be larger than 0 degrees and about 10 degrees or less. As a further example, the inclined angle AG1 between the second surface 100b of the first substrate 100 and the inclined surface 942 may be larger than 0 degrees and about 5 degrees or less.

In one embodiment, a thickness of at least a portion of the inclined portion 94 may decrease toward the outward direction. However, a change in thickness of the inclined portion 94 may not decrease toward the outward direction depending on a structure under the passivation pattern 90. Nonetheless, the level of at least a portion of the upper surface of the inclined portion 94 may decrease toward the outward direction.

At least a portion of the upper surface of the inclined portion 94, that is, the inclined surface 942, may include an upper end and a lower end. The upper end of the inclined surface 942 may be located inward from the lower end of the inclined surface. The upper end and the lower end of the inclined surface 942 may be spaced apart from the filtering pattern 80. For example, the lower end of the inclined surface 942 may be spaced apart from an upper surface of the filtering pattern 80 by a second vertical distance D2 in the vertical direction.

The passivation pattern 90 may include a dummy lens portion 92. The dummy lens portion 92 may include a plurality of dummy lenses 920. The dummy lenses 920 may be arranged laterally. The dummy lenses 920 may be arranged along at least a portion of a perimeter of the pixel array region AR (see FIG. 2). For example, the dummy lenses 920 may be arranged in a perimetric direction and the outward direction of the pixel array region AR (see FIG. 2).

Referring to FIGS. 2 and 3, each of at least portions of the dummy lenses 920 may vertically overlap one of the reference photodiodes 111. For example, each of the dummy lenses 920 adjacent to the pixel array region AR may vertically overlap one of the reference photodiodes 111. The dummy lenses 920 closest to the pixel array region AR among the dummy lenses 920 may be referred to as first dummy lenses 921. The dummy lenses 920 adjacent to the first dummy lenses 921 among the dummy lenses 920 may be referred to as second dummy lenses 922. The first dummy lenses 921 may vertically overlap the first reference photodiode region RPR1. The second dummy lenses 922 may vertically overlap the second reference photodiode region RPR2. The first dummy lenses 921 may be located between the second dummy lenses 922 and the pixel array region AR. The second dummy lenses 922 may be provided outside the first dummy lenses 921.

Referring back to FIG. 3, the dummy lenses 920 may include the remaining dummy lenses provided outside the second dummy lenses 922. The second dummy lenses 922 may be located between the first dummy lenses 921 and the remaining dummy lenses. The remaining dummy lenses may include third dummy lenses 923 adjacent to the second dummy lenses 922. In addition, although not shown, the remaining dummy lenses may include fourth, fifth, sixth dummy lenses, etc. The remaining dummy lenses may not overlap the reference photodiodes 111 (see FIG. 2).

Alternatively, each of the dummy lenses 920 may vertically overlap each of a plurality of reference photodiodes 111 (see FIG. 2) that are adjacent to each other.

Each of the dummy lenses 920 may have a shape that is convex upward in a cross-sectional view. In some embodiments, each of the dummy lenses 920 may have a circular shape or an elliptical shape in a plan view. An upper surface of the dummy lens 920 may include an upper end and a lower end. The upper end of the upper surface of the dummy lens 920 may be a portion or a point that is located at the highest level of the upper surface of the dummy lens 920. The lower end of the upper surface of the dummy lens 920 may be the other portion or the other point that is located at the lowest level of the upper surface of the dummy lens 920. The lower end of the upper surface of the dummy lens 920 may correspond to an edge of the upper surface of the dummy lens 920. The lower ends of the upper surfaces of neighboring dummy lenses 920 may be connected to each other.

The upper surfaces of the dummy lenses 920 may be spaced apart from the filtering pattern 80. For example, the upper ends and the lower ends of the upper surfaces of the dummy lenses 920 may be spaced apart from the upper surface of the filtering pattern 80. For example, the lower ends of the upper surfaces of the dummy lenses 920 may be spaced apart from the upper surface of the filtering pattern 80 by a first vertical distance D1 in the vertical direction. For example, the upper ends of the upper surfaces of the dummy lenses 920 may be spaced apart from the upper surface of the filtering pattern 80 by a third vertical distance D3 in the vertical direction.

In one embodiment, the second vertical distance D2 may be about 65% to about 100% of the first vertical distance D1. In an embodiment in which the first vertical distance D1 is larger than the second vertical distance D2, the second vertical distance D2 may be equal to or greater than 65% and less than 100% of the first vertical distance D1. As an example, the second vertical distance D2 may be about 70% to about 90% of the first vertical distance D1.

In one embodiment, the second vertical distance D2 may be about 5% to about 35% of the third vertical distance D3. For example, the second vertical distance D2 may be about 10% to about 30% of the third vertical distance D3.

The dummy lens portion 92 may be inclined entirely. This may include a level of the dummy lens portion 92 decreasing or increasing according to each specific unit. The specific unit may be a dummy lens 920 unit. For example, the level of the dummy lens portion 92 may decrease according to each dummy lens 920 unit. In one dummy lens 920 unit, the level may be measured based on a specific reference point. For example, the level of the dummy lens portion 92 may be measured based on the upper end or an edge of each of the dummy lens 920. Accordingly, the level of the dummy lens portion 92 may decrease toward the outward direction. Conversely, the level of the dummy lens portion 92 may increase toward the inward direction.

The dummy lens portion 92 may be inclined in the downward direction toward the outward direction. For example, levels of the upper ends of the dummy lenses 920 may decrease as the dummy lenses 920 extend away (i.e., are disposed further) from the pixel array region AR (see FIG. 2). In addition, the levels of the upper ends of the dummy lenses 920 may decrease as the dummy lenses 920 extend toward (i.e., are disposed closer to) the inclined portion 94. For example, a level of an upper end of the second dummy lens 922 may be lower than a level of an upper end of the first dummy lens 921, and a level of an upper end of the third dummy lens 923 may be lower than the level of the upper end of the second dummy lens 922. Accordingly, a common external tangent L1 of upper surfaces of the first dummy lens 921 to the third dummy lens 923 may be inclined in the downward direction toward the outward direction.

In one embodiment, sizes of each of the dummy lenses 920 may decrease toward the outward direction. For example, thicknesses of each of the dummy lenses 920 may decrease toward the outward direction. For example, diameters or widths of each of the dummy lenses 920 may decrease toward the outward direction. Accordingly, a slope of the common external tangent L1 of the upper surfaces of the first dummy lens 921 to the third dummy lens 923 may further increase. However, the present disclosure is not limited thereto, and the sizes of each of the dummy lenses 920 may also be the same as each other.

The common external tangent L1 of the upper surfaces of the first dummy lens 921 to the third dummy lens 923 may be located over the inclined portion 94. A level of an upper end of the inclined portion 94 may be lower than the levels of the upper ends of the dummy lenses 920. For example, the levels of the upper ends of the dummy lenses 920 closest to the inclined portion 94 among the dummy lenses 920 may be higher than the level of the upper end of the inclined portion 94. For example, the level H1 of the upper end of the third dummy lens 923 may be higher than the level of the upper end of the inclined portion 94.

In one embodiment, the levels of the upper ends of the dummy lenses 920 may be lower than levels of upper ends of the microlenses ML (see FIG. 2). For example, the level of the upper end of the first dummy lens 921 may be lower than the level of the upper end of the microlens ML (see FIG. 2). In one embodiment, the thicknesses of each of the dummy lenses 920 may be smaller than thicknesses of the microlenses ML (see FIG. 2).

The passivation pattern 90 may further include an edge portion 96 extending from the inclined portion 94. The edge portion 96 may be an end portion of the passivation pattern 90. The edge portion 96 may surround one side of the blocking pattern 50 and/or one side of the filtering pattern 80. In one embodiment, the edge portion 96 may further surround one side of the transmission insulating film 310.

The edge portion 96 may include an edge surface 962 extending from the inclined surface 942 of the inclined portion 94. The edge surface 962 may be at least a portion of an upper surface of the edge portion 96. The edge surface 962 may be inclined. A level of the edge surface 962 may decrease toward the outward direction. For example, the edge surface 962 may have a downward slope in a direction away from the inclined portion 94. As an example, the level of the edge surface 962 of the edge portion 96 may decrease as the edge surface 962 extends away from the inclined portion 94. In one embodiment, the edge surface 962 of the edge portion 96 may be an upper surface inclined with a constant slope.

For example, an inclination angle AG2 between the second surface 100b of the first substrate 100 and the edge surface 962 may be about 80 degrees or more and less than about 90 degrees. As a further example, the inclination angle AG2 between the second surface 100b of the first substrate 100 and the edge surface 962 may be about 85 degrees or more and less than about 90 degrees.

Alternatively, although not shown, in one embodiment, the edge surface 962 of the edge portion 96 may be a curved surface that is concave in the downward direction.

The edge surface 962 of the edge portion 96 may be steeper than the inclined surface 942 of the inclined portion 94. For example, a slope of the edge surface 962 of the edge portion 96 may be larger than a slope of the inclined surface 942 of the inclined portion 94. A level of an upper end of the edge portion 96 may be lower than the level of the upper end of the inclined portion 94. The level of the upper end of the edge portion 96 may be lower than a level of a lower end of the inclined portion 94.

A length in which the inclined surface 942 obliquely extends may be larger than a length in which the edge surface 962 obliquely extends. For example, in a cross-sectional view, the length of the inclined surface 942 is greater than the length of the edge surface 962. The length in which the inclined surface 942 extends or the length in which the edge surface 962 extends may be measured laterally. For example, a first length LT1 in which the inclined surface 942 obliquely extends may be about 60 times or more a second length LT2 in which the edge surface 962 obliquely extends.

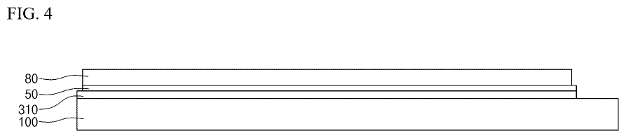

FIGS. 4 to 8 show a manufacturing method of an image sensor 1 according to some embodiments of the present disclosure, which are cross-sectional views corresponding to line I-I′ of FIG. 1.

Referring to FIG. 2 and FIG. 4, the transmission insulating film 310 may be formed on the first substrate 100. For example, the transmission insulating film 310 may be formed on one surface of the first substrate 100. The one surface of the first substrate 100 may be a light incident surface. The transmission insulating film 310 may be formed on the pixel array region AR (see FIG. 2) and the optical black region OBR (see FIG. 2).

The blocking pattern 50 may be formed on the transmission insulating film 310. Therefore, the blocking pattern 50 may be stacked on the transmission insulating film 310. The blocking pattern 50 may include a metal material. For example, the blocking pattern 50 may include tungsten.

The filtering pattern 80 may be formed on the transmission insulating film 310. Therefore, the filtering pattern 80 may be stacked on the blocking pattern 50. The filtering pattern 80 may include a color filter that transmits light of a specific wavelength range. For example, the filtering pattern 80 may include a blue color filter that primarily transmits blue light.

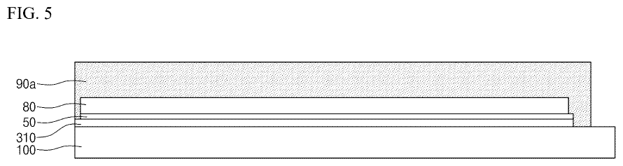

Referring to FIG. 5, a passivation film 90a may be formed on the transmission insulating film 310, the blocking pattern 50, and the filtering pattern 80 that are stacked on the first substrate 100. The passivation film 90a may cover the filtering pattern 80 and the blocking pattern 50. The passivation film 90a may further cover the transmission insulating film 310. The passivation film 90a may also be formed on the first substrate 100. For example, the passivation film 90a may contact a top surface of the filtering pattern 80 and the second surface 100b of the first substrate 100. The passivation film 90a may also contact first and second side surfaces of each of the filtering pattern 80 and blocking pattern 50. In an embodiment, the filtering pattern 80 may not extend across the entire top surface of the blocking pattern 50. In such an embodiment, the passivation film 90a may contact the top surface blocking pattern 50.

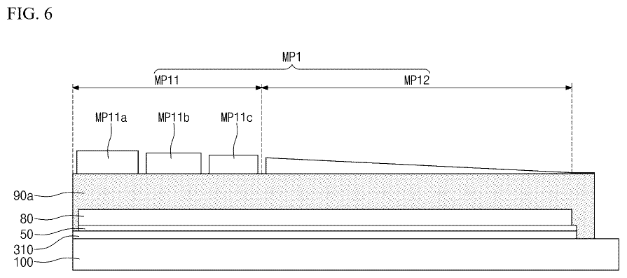

Referring to FIG. 6, a first mask pattern MP1 may be formed on the passivation film 90a. The first mask pattern MP1 may be formed with different thicknesses on the passivation film 90a. The first mask pattern MP1 may be formed so that its thickness decreases toward the outward direction. For example, the first mask pattern MP1 may be formed through gray scale lithography.

The first mask pattern MP1 may include a first mask portion MP11 whose thickness stepwise decreases. The first mask portion MP11 may be formed adjacent to the pixel array region AR (see FIG. 2). A thickness of the first mask portion MP11 may stepwise decrease toward the outward direction. For example, the first mask pattern MP1 may include at least one of a first portion MP11a, a second portion MP11b, and a third portion Mp11c that have different thicknesses.

The first portion MP11a to the third portion MP11c may be sequentially arranged in the outward direction. The first portion MP11a may be closest to the pixel array region AR (see FIG. 2). The second portion MP11b may be adjacent to the first portion MP11a. The third portion MP11c may be adjacent to the second portion MP11b. A thickness of the first portion MP11a may be thicker than a thicknesses of the second portion MP11b and a thicknesses of the third portion MP11c. The thickness of the second portion MP11b may be thicker than the thickness of the third portion MP11c. Accordingly, the thickness of the first mask portion MP11 may stepwise decrease toward the outward direction.

The first portion MP11a to the third portion MP11c may be spaced apart from each other. Therefore, openings may be formed between the first portion MP11a and the second portion MP11b and between the second portion MP11b and the third portion MP11c.

The first mask pattern MP1 may include a second mask portion MP12 whose thickness gradually decreases. The second mask portion MP12 may be formed adjacent to the first mask portion MP11. In one embodiment, the second mask portion MP12 may be spaced apart from the first mask portion MP11.

The thickness of the second mask portion MP12 may gradually decrease toward the outward direction. For example, the thickness of the second mask portion MP12 may linearly decrease toward the outward direction. Accordingly, an upper surface of the second mask portion MP12 may be formed to be inclined in the downward direction toward the outward direction.

The maximum thickness of the second mask portion MP12 may be smaller than the minimum thickness of the first mask portion MP11. For example, the maximum thickness of the second mask portion MP12 may be smaller than the thickness of the third portion MP11c.

The first mask pattern MP1 may not be formed on an end portion of the passivation film 90a. Accordingly, the end portion of the passivation film 90a may be exposed.

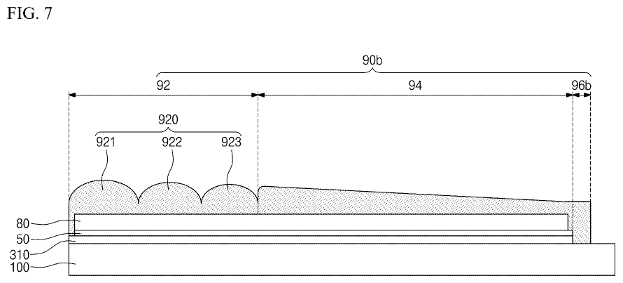

Referring to FIG. 7, an etching process may be performed using the first mask pattern MP1 as an etching mask. The etching process may be an anisotropic etching process. Therefore, a preliminary passivation pattern 90b may be formed. At least one of the dummy lens portion 92 or the inclined portion 94 may be formed in the preliminary passivation pattern 90b. For example, the dummy lenses 920 may be formed under the first mask portion MP11. The inclined portion 94 may be formed under the second mask portion MP12.

For example, the first dummy lens 921 may be formed under the first portion MP11a of the first mask portion MP11. The second dummy lens 922 may be formed under the second portion MP11b of the first mask portion MP11. The third dummy lens 923 may be formed under the third portion MP11c of the first mask portion MP11. Since the thicknesses stepwise decreases in the order of the first portion MP11a, the second portion MP11b, and the third portion MP11c, the thicknesses of the first dummy lens 921 to the third dummy lens 923 may also stepwise decrease in the formed order of the first dummy lens 921, the second dummy lens 922, and the third dummy lens 923.

A preliminary edge portion 96b may be formed at the end portion of the passivation film 90a in which the first mask pattern MP1 is not formed. In this case, an upper surface of the preliminary edge portion 96b may be formed flat in a horizontal direction.

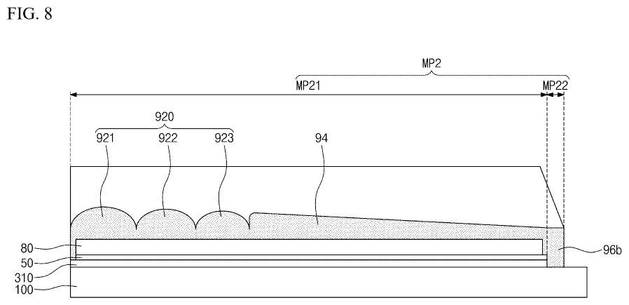

Referring to FIG. 8, a second mask pattern MP2 may be formed on the preliminary passivation pattern 90b. The second mask pattern MP2 may include a third mask portion MP21 formed on the dummy lens portion 92 and/or the inclined portion 94. The third mask portion MP21 may cover the dummy lens portion 92 and the inclined portion 94 that are formed. The third mask portion MP21 may include a flat upper surface in the horizontal direction.

The second mask pattern MP2 may include a fourth mask portion MP22 formed on the preliminary edge portion 96b. The fourth mask portion MP22 may cover the upper surface of the preliminary edge portion 96b. A thickness of the fourth mask portion MP22 may decrease toward the outward direction. An upper surface of the fourth mask portion MP22 may be inclined in the downward direction toward the outward direction. A level of an upper end of the fourth mask portion MP22 may be lower than a level of the upper surface of the third mask portion MP21. The minimum thickness of the third mask portion MP21 may be larger than the maximum thickness of the fourth mask portion MP22.

An etching process may be performed using the second mask pattern MP2 as an etching mask. Since the minimum thickness of the third mask portion MP21 is larger than the maximum thickness of the fourth mask portion MP22, the third mask portion MP21 may remain while the fourth mask portion MP22 is completely etched. Accordingly, while the preliminary edge portion 96b is etched, the dummy lens portion 92 or the inclined portion 94 may not be etched. Therefore, the edge portion 96 having the inclined edge surface 962 (see FIG. 3) may be formed.

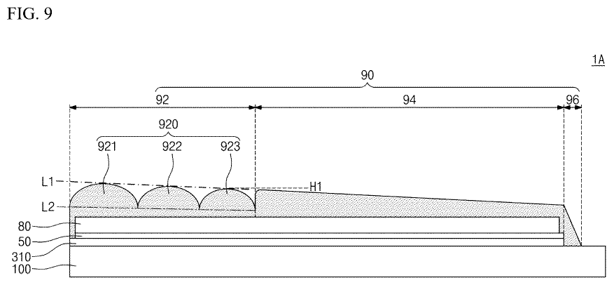

FIG. 9 is a cross-sectional view of an image sensor 1A according to one embodiment of the present disclosure.

Referring to FIGS. 3 and 9, the dummy lens 920 may have an upper surface that is convex in the upward direction. The upper surface of the dummy lens 920 may include an upper end and a lower end. The upper end of the upper surface of the dummy lens 920 may be a portion or a point that is located at the highest level of the upper surface of the dummy lens 920. The lower end of the upper surface of the dummy lens 920 may be the other portion or the other point that is located at the lowest level of the upper surface of the dummy lens 920. The lower end of the upper surface of the dummy lens 920 may correspond to an edge of the upper surface of the dummy lens 920. The lower ends of the upper surfaces of neighboring dummy lenses 920 may be connected to each other.

Referring to FIG. 3, in one embodiment, the lower ends of the upper surfaces of the dummy lenses 920 may be located at the same level. However, levels of the upper ends of the dummy lenses 920 provided on the same level may decrease toward the outward direction.

Alternatively, referring to FIG. 9, in one embodiment, the lower ends of the upper surfaces of the dummy lenses 920 may be located at different levels. The levels of the lower ends of the upper surfaces of the dummy lenses 920 may decrease toward the outward direction. Accordingly, a virtual line L2 connecting the lower ends of the upper surfaces of the dummy lenses 920 may be inclined in the downward direction toward the outward direction. In addition, a slope of a common external tangent L1 of the upper surfaces of the dummy lenses 920 may further increase.

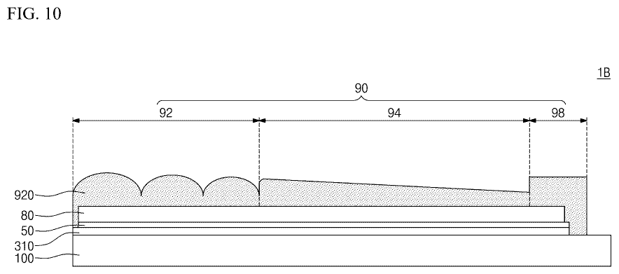

FIG. 10 is a cross-sectional view of an image sensor 1B according to one embodiment of the present disclosure.

Referring to FIG. 10, in one embodiment, the passivation pattern 90 may include a protrusion 98 protruding in an upward direction. The protrusion 98 may be connected to one end portion of the inclined portion 94. The one end portion of the inclined portion 94 may be adjacent to the outermost surface of the first substrate 100. The other end portion of the inclined portion 94 may be connected to the dummy lens portion 92 or the pixel array region AR (see FIG. 2). The protrusion 98 may surround one side of the filtering pattern 80 and/or one side of the blocking pattern 50.

The protrusion 98 may include a flat upper surface. The upper surface of the protrusion 98 may protrude in the upward direction from one end of the upper surface of the inclined portion 94. For example, a level of the upper surface of the protrusion 98 may be higher than the level of the lower end of the inclined portion 94. The upper surface of the protrusion 98 may be horizontal (e.g., flat, planar).

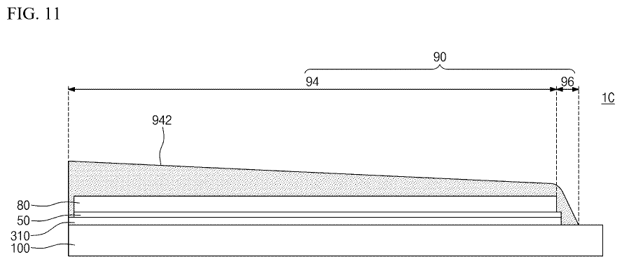

FIG. 11 is a cross-sectional view of an image sensor 1C according to one embodiment of the present disclosure.

Referring to FIG. 11, in one embodiment, the inclined portion 94 may extend from the pixel array region AR (see FIG. 2) to the edge portion 96. The inclined portion 94 may be connected to the pixel array region AR (see FIG. 2). The inclined portion 94 may extend in the outward direction. In this case, the dummy lens portion 92 may be omitted.

A level of at least a portion of an upper surface of the inclined portion 94 may decrease toward the outward direction. For example, the upper surface of the inclined portion 94 may include the inclined surface 942 whose level decreases toward the outward direction. The inclined surface 942 may be inclined in the downward direction toward the outward direction. For example, a level of the inclined surface 942 may linearly decrease toward the outward direction.

Alternatively, in one embodiment, the upper surface of the inclined portion 94 may include a curved surface that is concave in the downward direction. A slope of the concave curved surface may become gentler toward the outward direction. The slope of the concave curved surface may gradually decrease toward the outward direction.

In one embodiment, a thickness of at least a portion of the inclined portion 94 may decrease toward the outward direction. However, a change in thickness of the inclined portion 94 may not decrease depending on a structure under the passivation pattern 90. Nonetheless, the level of at least a portion of the upper surface of the inclined portion 94 may decrease toward the outward direction.

A level of an upper end of the inclined portion 94 may be lower than the levels of the upper ends of the microlenses ML provided in the pixel array region AR (see FIG. 2). Accordingly, the upper surface of the inclined portion 94 may be located at a lower level than the upper ends of the microlenses ML.

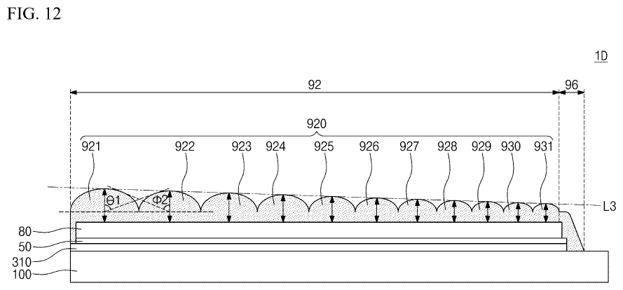

FIG. 12 is a cross-sectional view of an image sensor 1D according to one embodiment of the present disclosure.

Referring to FIG. 12, in one embodiment, the dummy lens portion 92 may extend from the pixel array region AR (see FIG. 2) to the edge portion 96. The dummy lens portion 92 may be connected to the pixel array region AR (see FIG. 2). The dummy lens portion 92 may extend in the outward direction. In this case, the inclined portion 94 may be omitted.

The dummy lens portion 92 may include a plurality of dummy lenses 920. The dummy lenses 920 may be arranged in the outward direction. The dummy lenses 920 may be arranged along at least a portion of a perimeter of the pixel array region AR (see FIG. 2). For example, the dummy lenses 920 may be arranged in the perimetric direction and the outward direction of the pixel array region AR (see FIG. 2).

Similar to FIG. 3, the dummy lenses 920 may include the first dummy lenses 921 to the third dummy lenses 923. The dummy lens 920 may further include the fourth, fifth, sixth dummy lenses 920, etc. For example, the dummy lenses 920 may include the first dummy lens 921 to an eleventh dummy lens 931. The first dummy lens 921 to the eleventh dummy lens 931 may be sequentially arranged in the outward direction. The first dummy lens 921 may be closest to the pixel array region AR (see FIG. 2), and the eleventh dummy lens 931 may be closest to the edge portion 96.

The dummy lens portion 92 may be inclined entirely (e.g., along the entire region from the pixel arrary region AR to the edge portion 96). The dummy lens portion 92 may be inclined in the downward direction toward the outward direction. A level of the dummy lens portion 92 may decrease for each dummy lens 920 unit. The level of the dummy lens portion 92 may decrease toward the outward direction. Conversely, the level of the dummy lens portion 92 may increase toward the inward direction.

For example, levels of upper ends of the dummy lenses 920 may decrease as the dummy lenses 920 extend away (i.e., are disposed further) from the pixel array region AR (see FIG. 2). In addition, the levels of the upper ends of the dummy lenses 920 may decrease as the dummy lenses 920 extend toward (i.e., are disposed closer to) the inclined portion 94. For example, the levels of the upper ends of the dummy lenses 920 may sequentially decrease from the first dummy lens 921 to the eleventh dummy lens 931. Accordingly, a common external tangent L3 of upper surfaces of the first dummy lens 921 to the eleventh dummy lens 931 may be inclined in the downward direction toward the outward direction.

In one embodiment, sizes of each of the dummy lenses 920 may decrease toward the outward direction. For example, thicknesses of each of the dummy lenses 920 may decrease toward the outward direction. For example, diameters or widths of each of the dummy lenses 920 may decrease toward the outward direction. Accordingly, a slope of the common external tangent L3 of the upper surfaces of the first dummy lens 921 to the eleventh dummy lens 931 may further increase. However, the present disclosure is not limited thereto, and the sizes of each of the dummy lenses 920 may also be the same as each other.

In one embodiment, the levels of the upper ends of the dummy lenses 920 may be lower than the levels of upper ends of the microlenses ML (see FIG. 2). For example, a level of an upper end of the first dummy lens 921 may be lower than the level of the upper end of the microlens ML (see FIG. 2). In one embodiment, the thicknesses of each of the dummy lenses 920 may be smaller than the thicknesses of the microlenses ML (see FIG. 2).

Each of the dummy lenses 920 may include an outer opening angle and an inner opening angle. The outer opening angle may refer to an angle at which a surface of the dummy lens 920 reflecting light is opened in the outward direction. The inner opening angle may refer to an angle at which the surface of the dummy lens 920 reflecting light is opened in the inward direction.

For example, the first dummy lens 921 may have a first outer opening angle θ1. The first outer opening angle θ1 may be an angle between portions of a surface of the first dummy lens 921 that are not covered by the second dummy lens 922 and exposed toward the outward direction.

The second dummy lens 922 may have a second inner opening angle φ2. The second inner opening angle φ2 may be an angle between portions of a surface of the second dummy lens 922 that are not covered by the first dummy lens 921 and exposed toward the inward direction.

In one dummy lens unit, the outer opening angle may be larger than the inner opening angle. This may be because the levels of the upper ends of the dummy lenses 920 decreases toward the outward direction. In the neighboring dummy lenses 920, the outer opening angle of the dummy lens 920 disposed relatively inward may be larger than the inner opening angle of the dummy lens 920 disposed relatively outward. For example, in the first dummy lens 921 and the second dummy lens 922, the first outer opening angle θ1 may be larger than the second inner opening angle φ2. Therefore, the dummy lens portion 92 may guide a larger amount of light to the outward direction.

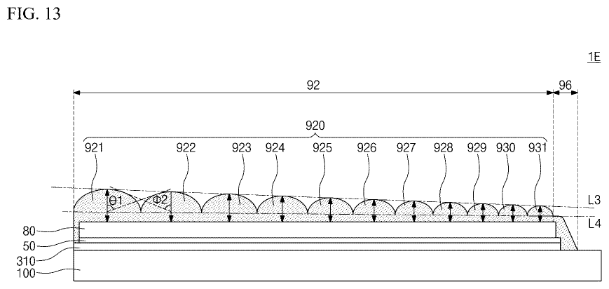

FIG. 13 is a cross-sectional view of an image sensor 1E according to one embodiment of the present disclosure.

Referring to FIG. 13, in one embodiment, lower ends of upper surfaces of the dummy lenses 920 may be located at different levels. Levels of the lower ends of the upper surfaces of the dummy lenses 920 may decrease toward the outward direction. For example, the levels of the lower ends of the upper surfaces of the dummy lenses 920 may decrease from the first dummy lens 921 to the eleventh dummy lens 931. Accordingly, a virtual line L4 connecting the lower ends of the upper surfaces of the dummy lenses 920 may be inclined in the downward direction toward the outward direction. In addition, a slope of a common external tangent L3 of the upper surfaces of the dummy lenses 920 may further increase.

Since the levels of the lower ends of the upper surfaces of the dummy lenses 920 decrease toward the outward direction, outer opening angles of the dummy lenses 920 may further increase and inner opening angles may decrease. For example, compared to FIG. 12, a first outer opening angle θ1 in FIG. 13 may increase, and a second inner opening angle φ2 may decrease.

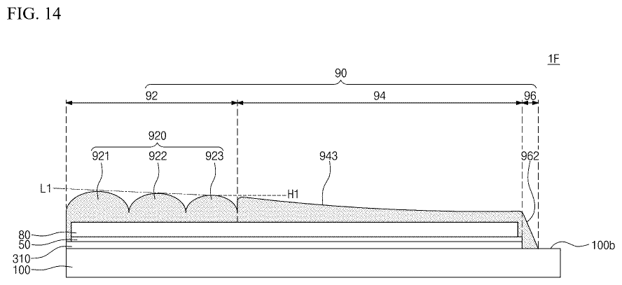

FIG. 14 is a cross-sectional view of an image sensor 1F according to one embodiment of the present disclosure.

Referring to FIG. 14, in one embodiment, an upper surface of the inclined portion 94 may include a curved surface 943 that is concave in the downward direction. A slope of the concave curved surface 943 may become gentler toward the outward direction. The slope of the concave curved surface 943 may gradually decrease toward the outward direction. Accordingly, the passivation pattern 90 may reflect some of incident light in a further outward direction.

According to embodiments of the present disclosure, due to an inclined portion provided on an optical black region and in which a level of at least a portion of an upper surface thereof decreases as the inclined portion extends away from a pixel array region, a passivation pattern can reflect incident light more outwardly. For example, an incident angle of incident light and a reflection angle of reflected light for the passivation pattern can be increased. Therefore, the phenomenon of light reflected from an upper surface of the passivation pattern being reflected again and incident onto the pixel array region can be reduced. As a result, flare phenomenon can be improved.

In addition, according to embodiments of the present disclosure, due to the upper surface of the inclined portion that is concave in a downward direction, the incident angle of incident light and the reflection angle of reflected light for the passivation pattern can be further increased. As a result, the flare phenomenon can be further improved.

In addition, according to embodiments of the present disclosure, since levels of upper ends of a plurality of dummy lenses decrease toward an outward direction, the dummy lens portion can have a structure that is entirely inclined in a downward direction toward an outward direction. Therefore, the phenomenon of light reflected from the dummy lens portion being reflected again and incident onto the pixel array region can be reduced. As a result, the flare phenomenon can be improved.

In addition, according to embodiments of the present disclosure, since upper surfaces of a plurality of dummy lenses are arranged to be stepwise lower toward the outward direction, the inclination of the dummy lens portion of an entirely inclined structure can become steeper. In addition, an angle at which each of the dummy lenses is exposed in the outward direction can be further increased, and an angle at which each of the dummy lenses is exposed in the inward direction can be further decreased. As a result, the flare phenomenon can be further improved.

In addition, according to embodiments of the present disclosure, since the widths of the plurality of dummy lenses become smaller toward the outward direction, the inclination of the dummy lens portion of an entirely inclined structure can become steeper. In addition, an angle at which each of the dummy lenses is exposed in the outward direction can be further increased, and an angle at which each of the dummy lenses is exposed in the inward direction can be further decreased. As a result, the flare phenomenon can be further improved.

In addition, according to embodiments of the present disclosure, since a level of an upper end of the inclined portion is lower than levels of upper ends of the plurality of dummy lenses, the passivation pattern can have a structure that is entirely inclined in the downward direction toward the outward direction. Therefore, the phenomenon of light reflected from the passivation pattern being reflected again and incident onto the pixel array region can be reduced. As a result, the flare phenomenon can be improved.

In addition, according to embodiments of the present disclosure, due to an edge portion located at an end portion of the passivation pattern and in which a level of an upper surface thereof becomes lower toward the outward direction, the phenomenon of light reflected from the upper surface of the edge portion being reflected again and incident onto the pixel array area can be reduced. As a result, the flare phenomenon can be improved.

The above-described contents are specific embodiments for implementing the present disclosure. In addition to the above-described embodiments, the present disclosure will also include various modifications and changes to the above-described embodiments that may be made by those skilled in the art, such as combining the above-described embodiments art. Therefore, the scope of the present disclosure should not be limited to the above-described embodiments, but should be defined by the appended claims and their equivalents.

What is claimed is:

1. An image sensor comprising:
a substrate including a pixel array region and an optical black region provided at one side of the pixel array region, and having a first surface and a second surface that are opposite to each other, the second surface being a light incident surface;
a blocking pattern provided on the second surface of the substrate and overlapping the optical black region;
a filtering pattern provided on the blocking pattern; and
a passivation pattern covering the blocking pattern and the filtering pattern,
wherein the passivation pattern includes an inclined portion in which a level of at least a first portion of an upper surface thereof decreases as the inclined portion extends away from the pixel array region.

2. The image sensor of claim 1, wherein
the first portion of the upper surface of the inclined portion has a downward slope in a direction away from the pixel array region.

3. The image sensor of claim 1, wherein
the first portion of the upper surface of the inclined portion is concave in a downward direction.

4. The image sensor of claim 1, wherein
the passivation pattern further includes a dummy lens portion between the pixel array region and the inclined portion, and
the dummy lens portion includes a plurality of dummy lenses arranged laterally.

5. The image sensor of claim 4, wherein
levels of upper ends of the plurality of dummy lenses with respect to the second surface of the substrate decrease in a direction from the pixel array region toward the inclined portion.

6. The image sensor of claim 5, wherein
horizontal widths of the plurality of dummy lenses decrease in the direction from the pixel array region toward the inclined portion.

7. The image sensor of claim 5, wherein
a level of the uppermost end of the inclined portion with respect to the second surface of the substrate is lower than the levels of the upper ends of the plurality of dummy lenses.

8. The image sensor of claim 4, wherein
upper surfaces of the dummy lenses are curved surfaces that are convex in an upward direction, and
a first vertical distance from an upper surface of the filtering pattern to a lower end of the upper surface of the dummy lens closest to the pixel array region is larger than a second vertical distance from the upper surface of the filtering pattern to a lower end of the first portion of the upper surface of the inclined portion.

9. The image sensor of claim 8, wherein
the second vertical distance is equal to or greater than 65% and less than 100% of the first vertical distance.

10. The image sensor of claim 4, wherein
upper surfaces of the dummy lenses are curved surfaces that are convex in an upward direction,
a third vertical distance from an upper surface of the filtering pattern to an upper end of the upper surface of the dummy lens closest to the pixel array region is larger than a second vertical distance from the upper surface of the filtering pattern to a lower end of the first portion of the upper surface of the inclined portion, and
the second vertical distance is about 5% to about 35% of the third vertical distance.

11. The image sensor of claim 2, wherein
the passivation pattern further includes an edge portion extending from the inclined portion and surrounding one end portion of the blocking pattern and one end portion of the filtering pattern, and
a level of an upper surface of the edge portion with respect to the second surface of the substrate decreases as the edge portion extends away from the inclined portion.

12. The image sensor of claim 11, wherein
the upper surface of the edge portion has a downward slope in a direction away from the inclined portion.

13. The image sensor of claim 12, wherein
the upper surface of the edge portion is steeper than the first portion of the upper surface of the inclined portion.

14. The image sensor of claim 13, wherein
an inclination angle between the second surface of the substrate and the upper surface of the edge portion is equal to or greater than 80 degrees and less than 90 degrees, and
an inclination angle between the second surface of the substrate and the first portion of the upper surface of the inclined portion is larger than 0 degrees and is less than or equal to 10 degrees.

15. The image sensor of claim 1, wherein
the passivation pattern further includes a protrusion connected to one end portion of the inclined portion, and
the protrusion protrudes in an upward direction from one end of the upper surface of the inclined portion and has a flat upper surface.

16. The image sensor of claim 1, further comprising:
color filters provided on the second surface of the substrate and overlapping the pixel array region; and
microlenses covering the color filters,
wherein the passivation pattern includes the same material as the microlenses.

17. The image sensor of claim 1, wherein
the filtering pattern includes a blue color filter that transmits blue light, and
the blocking pattern includes a metal.

18. An image sensor comprising:
a substrate including a pixel array region and an optical black region provided at one side of the pixel array region, and having a first surface and a second surface that are opposite to each other, the second surface being a light incident surface;
a blocking pattern provided on the second surface of the substrate and overlapping the optical black region;
a filtering pattern provided on the blocking pattern; and
a passivation pattern covering the blocking pattern and the filtering pattern,
wherein
the passivation pattern includes dummy lenses arranged laterally, and
levels of upper ends of the dummy lenses with respect to the second surface of the substrate decrease as the dummy lenses extend away from the pixel array region.

19. The image sensor of claim 18, wherein
upper surfaces of the dummy lenses are curved surfaces that are convex in an upward direction, and
levels of lower ends of the upper surfaces of the dummy lenses with respect to the second surface of the substrate decrease as the dummy lenses extend away from the pixel array region.

20. The image sensor of claim 18, wherein
horizontal widths of the dummy lenses decrease as the dummy lenses extend away from the pixel array region.
